(19) United States
(12) Patent Application Publication
(10) Pub. No.: US 2026/0164960 A1
(43) Pub. Date: Jun. 11, 2026

(54) DISPLAY SUBSTRATE, MANUFACTURING METHOD THEREOF AND DISPLAY APPARATUS

(71) Applicants: Beijing BOE Technology Development Co., Ltd., Beijing (CN); BOE Technology Group Co., Ltd., Beijing (CN)

(72) Inventors: Hejin WANG, Beijing (CN); Jianbo XIAN, Beijing (CN)

(21) Appl. No.: 18/708,679

(22) PCT Filed: Apr. 26, 2023
(86) PCT No.: PCT/CN2023/090791

§ 371 Date: May 9, 2024

(51) Int. Cl. H10K 59/131; H10K 59/12; H10K 59/80

(52) U.S. Cl. CPC H10K 59/131; H10K 59/1201; H10K 59/8731

(57) ABSTRACT

Disclosed are a display substrate, a manufacturing method thereof and a display apparatus. The display substrate includes a base substrate, a plurality of island regions on a side of the base substrate, a plurality of bridge regions for connecting adjacent island regions and hole regions arranged between adjacent bridge regions; each island region includes at least one sub-pixel, and the plurality of bridge regions arranged at intervals are connected between two adjacent island regions; and at least one bridge region includes a first metal layer, a first organic layer and a second metal layer stacked in sequence in a direction away from the base substrate, the first metal layer in each bridge region includes a first signal line for connecting the sub-pixels in the adjacent island regions, and the second metal layer in each bridge region includes a second signal line for connecting the sub-pixels in the adjacent island regions.

### CROSS-REFERENCE TO RELATED APPLICATIONS

The application is a National Stage of International Application No. PCT/CN2023/090791, filed Apr. 26, 2023, which is hereby incorporated by reference in its entirety.

### TECHNICAL FIELD

The present disclosure relates to the technical field of display, in particular to a display substrate, a manufacturing method thereof and a display apparatus.

### BACKGROUND

With the development of display technology, organic light-emitting diodes (OLEDs for short), which may perform flexible display, promote diversification of display and gradually become a mainstream of the display technology. In some related arts, OLED flexible display apparatuses may achieve bending of two-dimensional surfaces, but are not suitable for display apparatuses (such as a wearable device) in a more complex condition for flexible requirements of display substrates.

In order to develop a display function of the OLED flexible display apparatuses, in some related arts, an island for preparing a pixel region and a bridge for wiring are formed by opening holes in base substrate materials of the OLED flexible display apparatuses, and stretching of the display apparatuses is implemented through the deformation of the bridge.

### SUMMARY

The present disclosure provides a display substrate, a manufacturing method thereof and a display apparatus, and solutions are as follows.

The present disclosure provides a display substrate, including a base substrate, a plurality of island regions on a side of the base substrate, a plurality of bridge regions for connecting adjacent island regions and hole regions arranged between adjacent bridge regions; where,
each island region includes at least one sub-pixel, and the plurality of bridge regions arranged at intervals are connected between two adjacent island regions; and
at least one bridge region includes a first metal layer, a first organic layer and a second metal layer stacked in sequence in a direction away from the base substrate, the first metal layer in each bridge region includes a first signal line for connecting the sub-pixels in the adjacent island regions, and the second metal layer in each bridge region includes a second signal line for connecting the sub-pixels in the adjacent island regions.

In some embodiments, in the above display substrate provided by embodiments of the present disclosure, each bridge region further includes a second organic layer arranged on a side of the second metal layer facing away from the base substrate, and an orthographic projection of the second organic layer on the base substrate and an orthographic projection of the first organic layer on the base substrate are both within a range of the base substrate.

In some embodiments, in the above display substrate provided by embodiments of the present disclosure, the first organic layer at least covers a top surface of the first signal line.

In some embodiments, in the above display substrate provided by embodiments of the present disclosure, the first organic layer further covers a side surface of the first signal line, and the first organic layer is arranged in contact with the base substrate.

In some embodiments, in the above display substrate provided by embodiments of the present disclosure, an orthographic projection of the second signal line on the base substrate fall within an orthographic projection the first organic layer on the base substrate.

In some embodiments, in the above display substrate provided by embodiments of the present disclosure, the second organic layer covers a top surface of the second signal line and a side surface of the second signal line, and the second organic layer is arranged in contact with the first organic layers.

In some embodiments, in the above display substrate provided by embodiments of the present disclosure, the second signal line at least covers a top surface of the first organic layer.

In some embodiments, in the above display substrate provided by embodiments of the present disclosure, the second signal line further covers a side surface of the first organic layer, and the second signal line is arranged in contact with the base substrate.

In some embodiments, in the above display substrate provided by embodiments of the present disclosure, the second organic layer covers the top surface of the second signal line and the side surface of the second signal line, and the second organic layer is arranged in contact with the base substrate.

In some embodiments, in the above display substrate provided by embodiments of the present disclosure, each bridge region further includes an inorganic layer arranged on a side of the second organic layer facing away from the base substrate, the inorganic layer covers the second organic layer and is arranged in contact with the base substrate, and the inorganic layer has a hollow-out structure.

In some embodiments, in the above display substrate provided by embodiments of the present disclosure, the inorganic layer includes a top structure arranged opposite to the base substrate and two side structures arranged in contact with the base substrate, and the top structure has a first hollow-out structure penetrating through the top structure in a thickness direction of the top structure.

In some embodiments, in the above display substrate provided by embodiments of the present disclosure, the top structure has a plurality of the first hollow-out structures evenly arranged at intervals in an extension direction of the second signal line.

In some embodiments, in the above display substrate provided by embodiments of the present disclosure, the side structure has a second hollow-out structure penetrating through the side structure in a thickness direction of the side structure.

In some embodiments, in the above display substrate provided by embodiments of the present disclosure, the second hollow-out structure is interconnected with the first hollow-out structure.

In some embodiments, in the above display substrate provided by embodiment of the present disclosure, the island region includes a first source-drain metal layer, a first planarization layer, a second source-drain metal layer and a second planarization layer stacked in sequence in the direction facing away from the base substrate, the first signal line is arranged on the same layer as the first source-drain metal layer, the first organic layer is arranged on the same layer as the first planarization layer, the second signal line is arranged on the same layer as the second source-drain metal layer, and the second organic layer is arranged on the same layer as the second planarization layer.

In some embodiments, in the above display substrate provided by embodiments of the present disclosure, the island region further includes a first inorganic encapsulation layer, an organic encapsulation layer and a second inorganic encapsulation layer stacked in sequence on a side of the second planarization layer facing away from the base substrate, the inorganic layer includes a first sub-inorganic layer and a second sub-inorganic layer arranged in a stacked mode, the first sub-inorganic layer is arranged on the same layer as the first inorganic encapsulation layer, and the second sub-inorganic layer is arranged on the same layer as the second inorganic encapsulation layer.

In some embodiments, in the above display substrate provided by embodiments of the present disclosure, a shape of the bridge region is a curve line, and a shape of the first signal line and a shape of the second signal line are the same as the shape of the bridge region.

In some embodiments, in the above display substrate provided by embodiments of the present disclosure, a distance between an edge of the orthographic projection of the first organic layer on the base substrate and an edge of an orthographic projection of the first signal line on the base substrate is greater than or equal to 1 μm, and a distance between an edge of the orthographic projection of the second organic layer on the base substrate and an edge of the orthographic projection of the second signal line on the base substrate is greater than or equal to 1 μm.

Correspondingly, embodiments of the present disclosure further provide a display apparatus, including the display substrate provided by embodiments of the present disclosure.

Correspondingly, embodiments of the present disclosure further provide a method for manufacturing a display substrate, including:
providing a base substrate, where the base substrate has a plurality of island regions, a plurality of bridge regions for connecting adjacent island regions and hole regions arranged between adjacent bridge regions, where the plurality of bridge regions arranged at intervals are connected between two adjacent island regions; and
forming at least one sub-pixel in each island region, and forming a first metal layer, a first organic layer and a second metal layer stacked in sequence in a direction facing away from the base substrate in at least one bridge region, where the first metal layer in each bridge region includes a first signal line for connecting the sub-pixels in the adjacent island regions, and the second metal layer in each bridge region includes a second signal line for connecting the sub-pixels in the adjacent island regions.

### BRIEF DESCRIPTION OF FIGURES

FIG. 1 is a schematic diagram of a plane structure of a display substrate provided by an embodiment of the present disclosure.

FIG. 2A is a schematic diagram of a local section structure of a display substrate provided by an embodiment of the present disclosure.

FIG. 2B is a schematic diagram of an amplified structure of three bridge regions in FIG. 2A.

FIG. 3A is a schematic diagram of yet another local section structure of a display substrate provided by an embodiment of the present disclosure.

FIG. 3B is a schematic diagram of arranging a hollow-out structure on a top structure of an inorganic layer of a bridge region.

FIG. 3C is a schematic diagram of arranging hollow-out structures on a top structure and side structures of an inorganic layer of a bridge region.

FIG. 3D is a schematic diagram of an amplified structure of three bridge regions Q2 in FIG. 3A.

FIG. 4A is a schematic diagram of yet another local section structure of a display substrate provided by an embodiment of the present disclosure.

FIG. 4B is a schematic diagram of an amplified structure of three bridge regions in FIG. 4A.

FIG. 5A is a schematic diagram of yet another local section structure of a display substrate provided by an embodiment of the present disclosure.

FIG. 5B is a schematic diagram of arranging a hollow-out structure on a top structure of an inorganic layer of a bridge region.

FIG. 5C is a schematic diagram of arranging hollow-out structures on a top structure and side structures of an inorganic layer of a bridge region.

FIG. 5D is a schematic diagram of an amplified structure of three bridge regions in FIG. 5A.

FIG. 6 is a schematic diagram of a pixel circuit of 2T1C.

FIG. 7 is a schematic diagram of a pixel circuit of 3T1C.

FIG. 8 is a schematic diagram of a pixel circuit of 7T1C.

FIG. 9 is a schematic flow diagram of a manufacturing method of a display substrate provided by an embodiment of the present disclosure.

FIG. 10A to FIG. 10T are schematic structural diagrams corresponding to a display substrate provided by an embodiment of the present disclosure in a manufacturing flow.

### DETAILED DESCRIPTION

To make the objectives, technical solutions and advantages of embodiments of the present disclosure clearer, the technical solutions of embodiments of the present disclosure will be clearly and completely described below in conjunction with accompanying drawings of embodiments of the present disclosure. Obviously, the described embodiments are a part of embodiments of the present disclosure, not all of them. In addition, embodiments of the present disclosure and features in the embodiments may be combined with each other without conflict. Based on the described embodiments of the present disclosure, all other embodiments obtained by those ordinarily skilled in the art without the need for creative labor fall within the scope of a protection of the present disclosure.

Unless otherwise defined, technical or scientific terms used in the present disclosure shall have the ordinary meanings understood by those ordinarily skilled in the art to which the present disclosure pertains. “Comprise”, “include” or similar words used in the present disclosure indicate that an element or item appearing before such words covers listed elements or items appearing after the words and equivalents thereof, and do not exclude other elements or items. “Connect”, “couple” or similar words are not limited to physical or mechanical connection, but may include electrical connection, no matter direct connection or indirection connection. “Inside”, “outside” “upper”, “lower”, etc. are merely used to show a relative position relation, and when an absolute position of a described object is changed, the relative position relation may also be correspondingly changed.

It should be noted that the size and shape of figures in the accompanying drawings do not reflect true scales, and are only aimed to illustrate the content of the present disclosure. Throughout same or similar reference signs indicate the same or similar elements or elements having the same or similar functions.

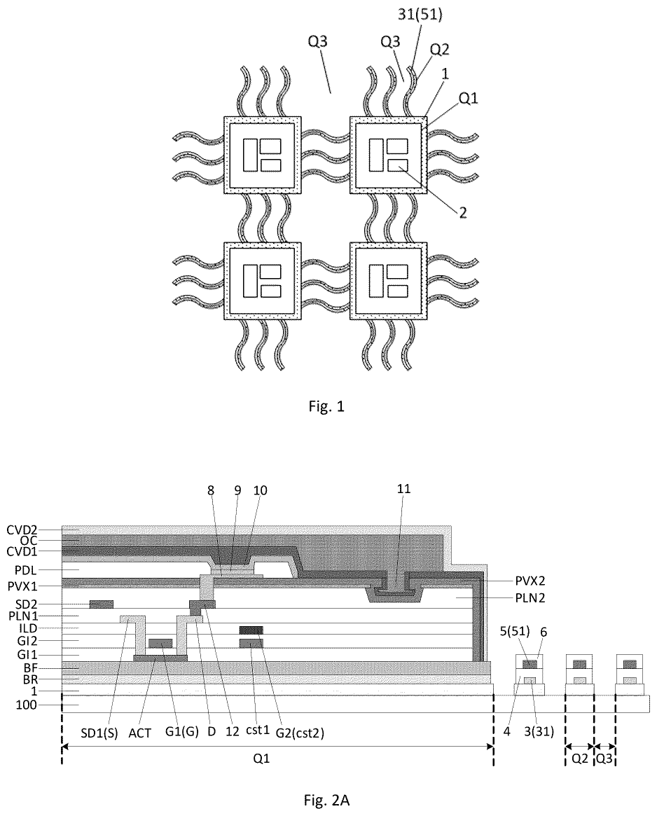

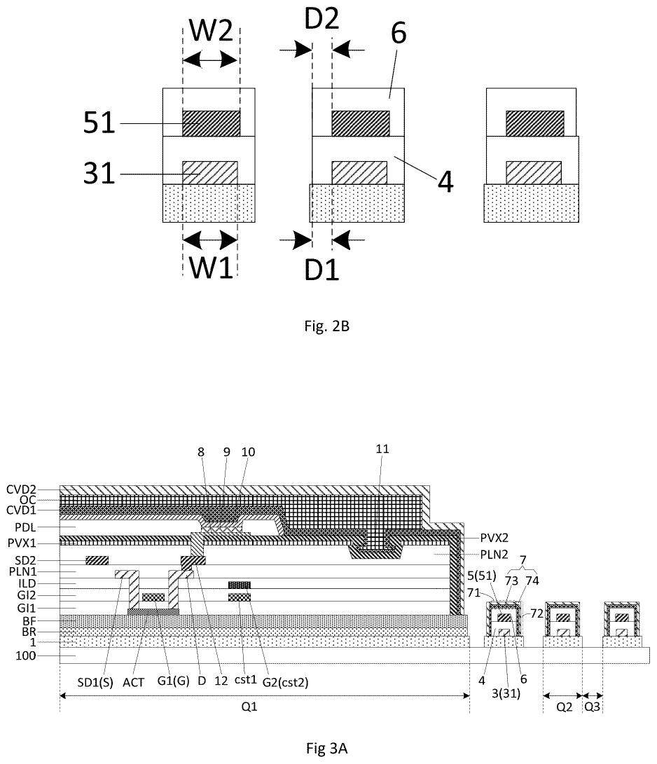

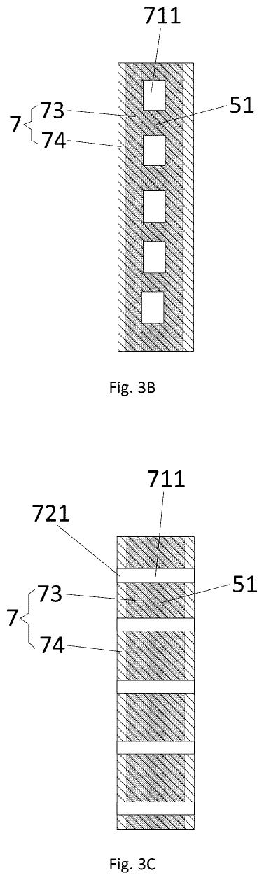

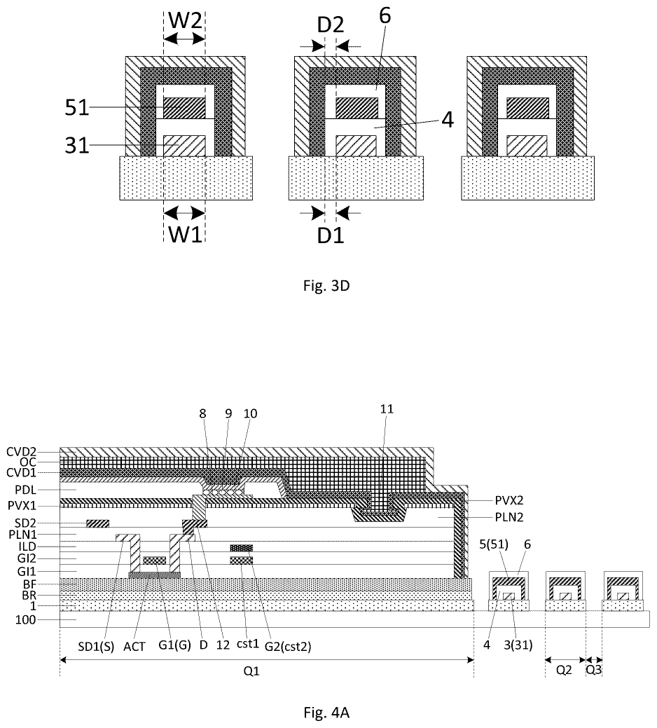

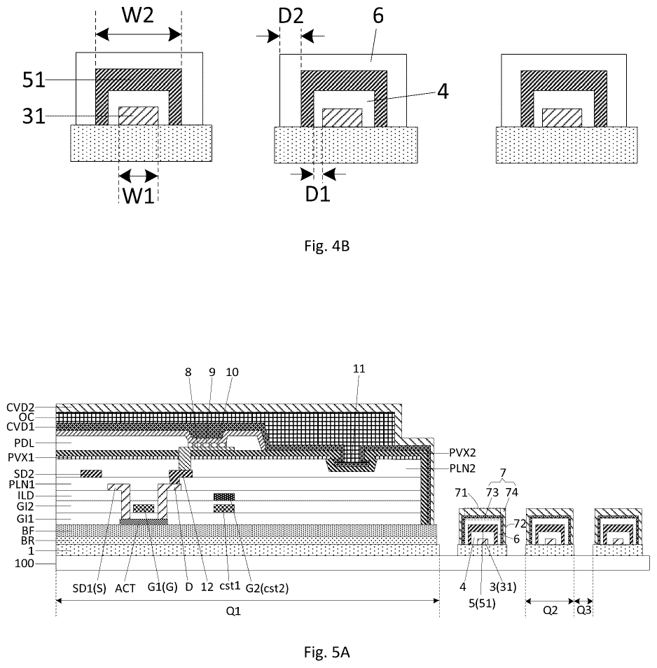

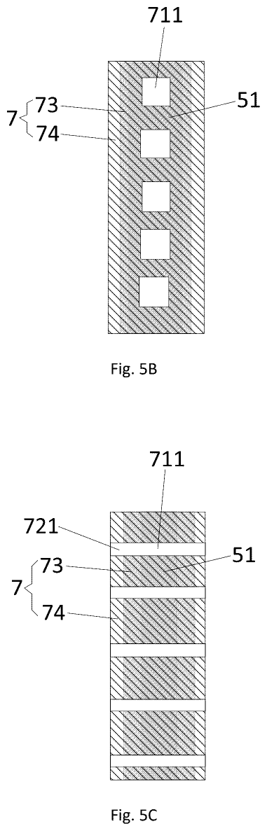

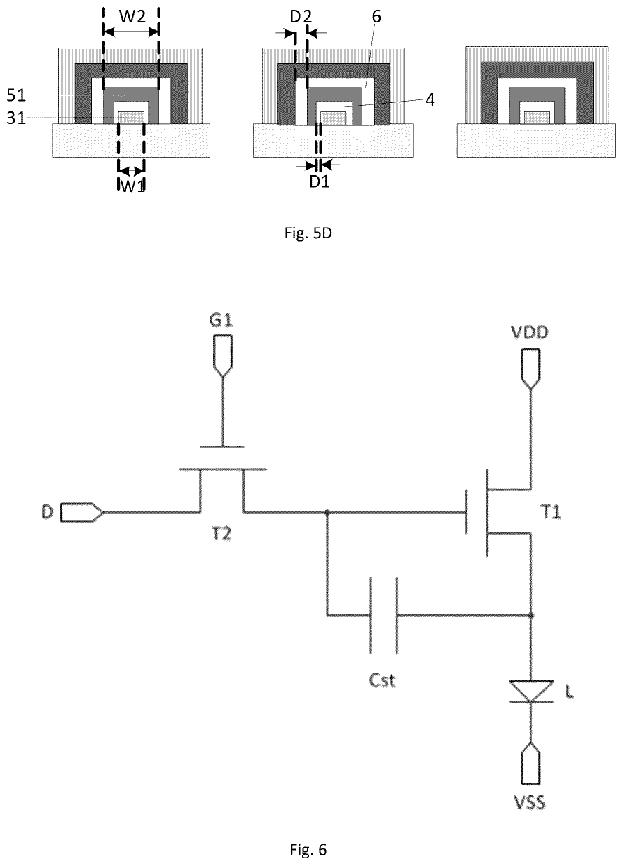

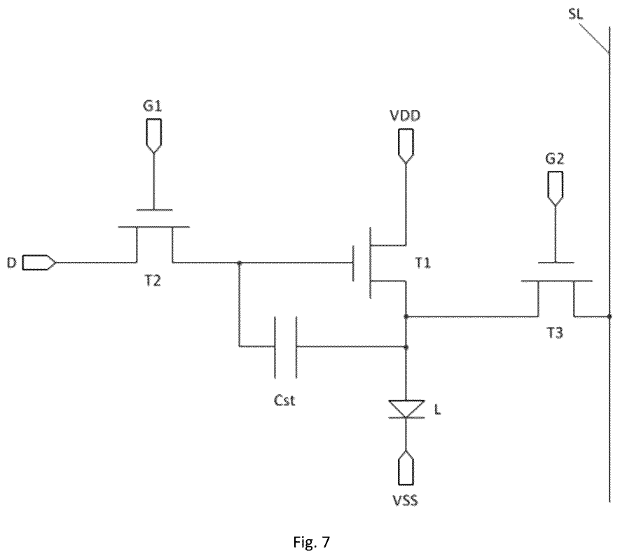

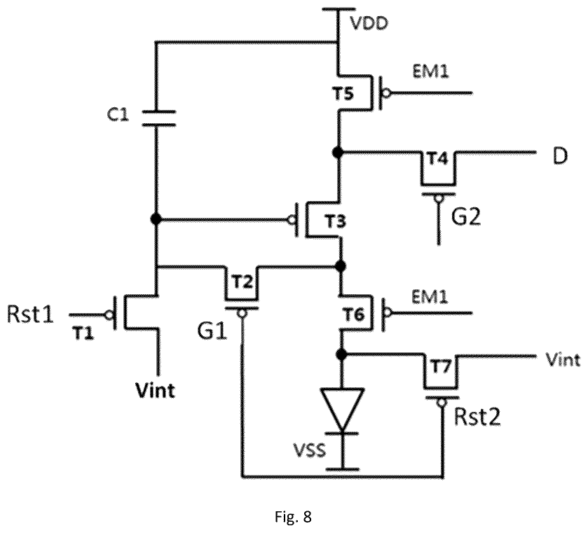

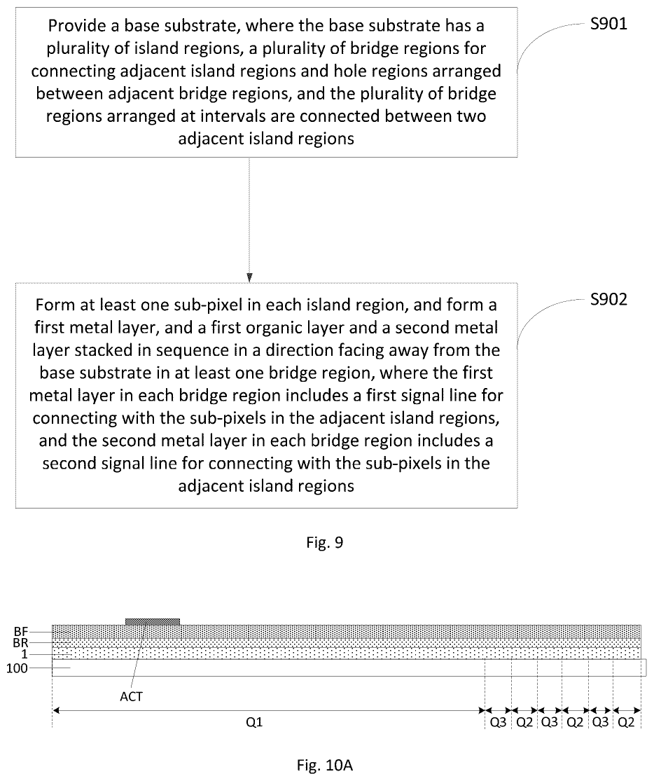

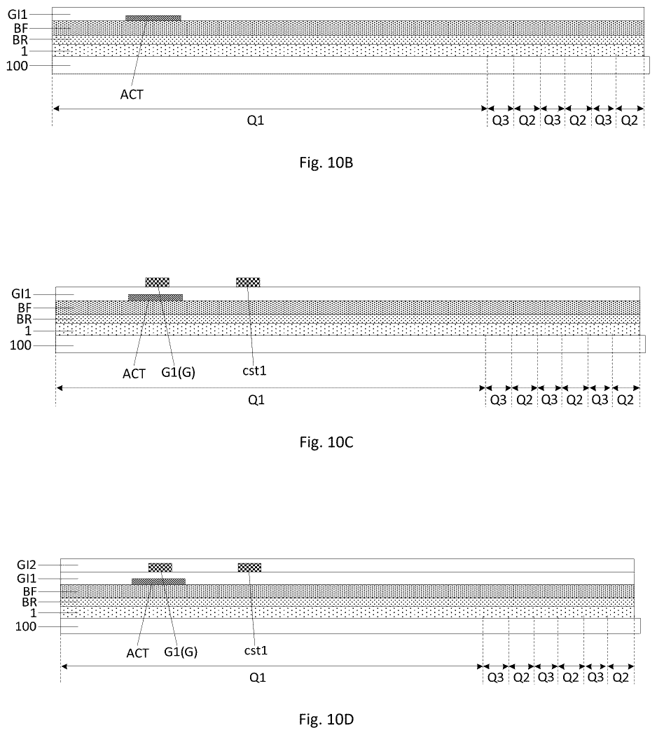

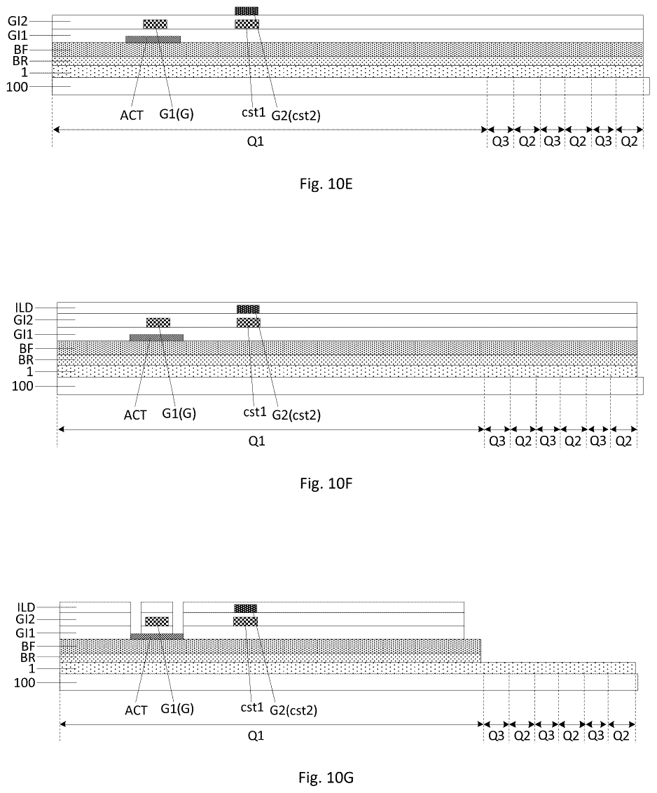

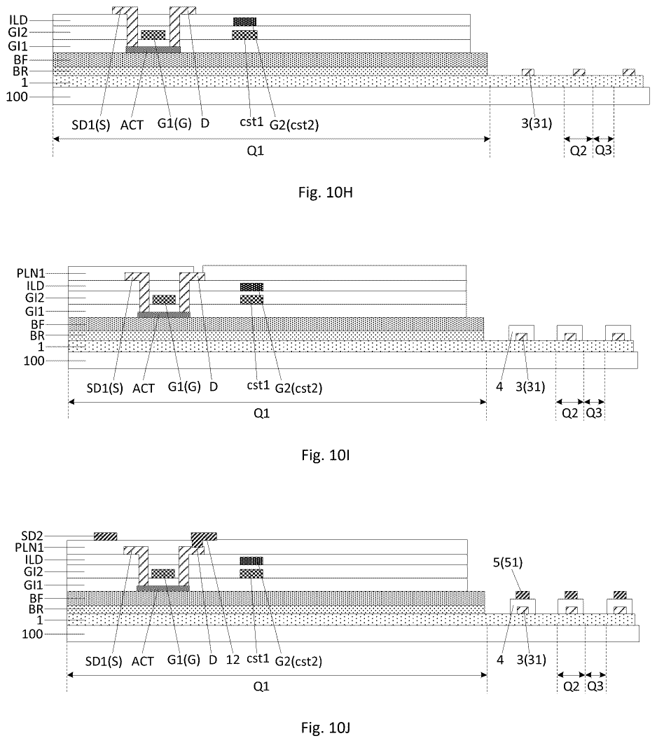

The present disclosure provides a display substrate, as shown in FIG. 1, FIG. 2A, FIG. 3A, FIG. 4A and FIG. 5A, FIG. 1 is a schematic diagram of a plane structure of the display substrate, FIG. 2A, FIG. 3A, FIG. 4A and FIG. 5A are respectively a schematic diagram of a local section structure of the display substrate, and the display substrate includes a base substrate 1, a plurality of island regions Q1 on a side of the base substrate 1, a plurality of bridge regions Q2 for connecting adjacent island regions Q1 and hole regions Q3 arranged between adjacent bridge regions Q2. In some embodiments, the island regions Q1 are for displaying images, the bridge regions Q2 are for wiring (connecting signals between the adjacent island regions Q1) and transferring tension, and the hole regions Q3 are for providing deformation space for the display substrate when stretched.

Each island region Q1 includes at least one sub-pixel 2, and the plurality of bridge regions Q2 arranged at intervals are connected between two adjacent island regions Q1; FIG. 1 provided in the present disclosure takes each island region Q1 including three sub-pixels 2 as an example, the three sub-pixels 2 may be a red sub-pixel R, a green sub-pixel G and a blue sub-pixel B respectively, but certainly are not limited to this; and the island regions Q1 in FIG. 2A, FIG. 3A, FIG. 4A and FIG. 5A only show a schematic diagram of a section structure of one sub-pixel respectively.

At least one bridge region Q2 incudes a first metal layer 3, a first organic layer 4 and a second metal layer 5 stacked in sequence in a direction facing away from the base substrate 1, the first metal layer 3 of each bridge region Q2 includes a first signal line 31 for connecting the sub-pixels 2 in the adjacent island regions Q1, and the second metal layer 5 of each bridge region Q2 includes a second signal line 51 for connecting the sub-pixels 2 in the adjacent island regions Q1.

According to the display substrate provided by embodiments of the present disclosure, signal line strength of the bridge regions may be increased by arranging the plurality of independent bridge regions for connecting two adjacent island regions between the two adjacent island regions, and adopting double-layer metal wiring design in the bridge regions, so that the signal lines of the bridge regions are not prone to breaking when the display substrate is removed down from a rigid base substrate in a preparation process.

In some embodiments, the base substrate may be a flexible base substrate, so that a stretchable region of the display substrate may be stretched, and the base substrate may include a flexible layer, and may also include a first flexible layer, a barrier layer and a second flexible layer arranged in a stacked mode. Embodiments of the present disclosure take the base substrate including the flexible layer as an example. In some embodiments, a material of the flexible layer may be polyimide (PI), polyester, polyamide, etc.

In some embodiments, as shown in FIG. 2A, FIG. 3A, FIG. 4A and FIG. 5A, the base substrate 1 and film layers on the base substrate may be arranged on a glass substrate 100 with a supporting function, and the glass substrate 100 is stripped after each film layer is manufactured, so as to obtain a stretchable display substrate to become the stretchable display substrate.

It should be noted that, as shown in FIG. 2A, FIG. 3A, FIG. 4A and FIG. 5A, the hole regions Q3 in embodiments of the present disclosure may fully penetrate through the display substrate, and certainly, the hole regions Q3 may also penetrate through all the film layers on the base substrate 1 and part of base substrate 1 of the display substrate. Embodiments of the present disclosure take the hole regions Q3 completely penetrating through the display substrate as an example.

In some embodiments, in the above display substrate provided by embodiments of the present disclosure, as shown in FIG. 1, FIG. 2A, FIG. 3A, FIG. 4A and FIG. 5A, the same metal layer of the bridge regions Q2 is only provided with one signal line, which may reduce the width of the bridge regions Q2, and increase a length of the bridge regions Q2, and a modulus of the bridge regions Q2 is reduced by removing the corresponding inorganic layers of the bridge regions, which may effectively improve a stretching capacity. The embodiment of the present disclosure takes the display substrate as the stretchable display substrate as an example for illustration.

In some embodiments, in the above display substrate provided by embodiments of the present disclosure, as shown in FIG. 1, FIG. 2A, FIG. 3A, FIG. 4A and FIG. 5A, each bridge region Q2 adopts first metal layer 3/second metal layer 5 double-layer metal wiring design, so that the first signal line 31 of the first metal layer 3 and the second signal line 51 of the second metal layer 5 may be designed as independent signal lines, that is, dual-layer wiring is performed on the signal lines in the display substrate, which may reduce the quantity of the bridge regions Q2, so that there is more space to design a bending structure of the bridge region Q2, and a stretching property is further improved.

In some embodiments, in the above display substrate provided by embodiments of the present disclosure, as shown in FIG. 2A, FIG. 3A, FIG. 4A and FIG. 5A, each bridge region Q2 also includes a second organic layer 6 located on a side of the second metal layer 5 facing away from the base substrate, and orthographic projections of the second organic layer 6 and the first organic layer 4 on the base substrate 1 are both within a range of the base substrate 1. In this way, each bridge region Q2 adopts a multi-layer metal/organic film layer alternatively arranged by the first signal line 31/the first organic layer 4/the second signal line 51/the second organic layer 6, which makes the film layer of the bridge region Q2 thicker, thereby increasing the strength of the bridge region Q2. In addition, due to a low breaking elongation of the inorganic layer, cracking is prone to happening first and cracking of the signal lines is caused, which reduces the overall stretching property. Therefore, there is no inorganic layer in direct contact on an upper and the lower adjacent to the two metal layers of the bridge region Q2 of the present disclosure, which may avoid fractures of the signal lines and further improve the stretching property.

In some embodiments, in order to protect each first signal line from erosion by subsequent manufacturing processes, in the display substrate provided by embodiments of the present disclosure, as shown in FIG. 2A, FIG. 3A, FIG. 4A and FIG. 5A, each first organic layer 4 at least covers a top surface of the first signal line 31.

In some embodiments, in the above display substrate provided by embodiments of the present disclosure, as shown in FIG. 2A, FIG. 3A, FIG. 4A and FIG. 5A, each first organic layer 4 also covers a side surface of the first signal line 31, and the first organic layer 4 is arranged in contact with the base substrate 1. Therefore, on one hand, the first organic layer 4 completely wraps the first signal line 31, which not only protects all positions of the first signal line 31 from erosion, but also improves the strength of the first signal line 31. On the other hand, since the first signal line 31 and the second signal line 51 of the upper metal layer and the lower metal layer are the independent signal lines, the first organic layer 4 completely wraps the first signal line 31 to avoid short circuits in the signal lines of the upper metal layer and the lower metal layer.

In some embodiments, as shown in FIG. 2A, FIG. 3A, FIG. 4A and FIG. 5A, in each bridge region Q2, the first organic layer 4 wraps both sides of the first signal line 31, and an orthographic projection of the first organic layer 4 on the glass substrate 100 is located within an orthographic projection range of the base substrate 1 on the glass substrate 100; and certainly, the first organic layer 4 may also not wrap both sides of the first signal line 31, and a width of the first organic layer 4 is larger than a width of the first signal line 31, and a width of the first organic layer 4 is smaller than a width of the base substrate 1.

In some embodiments, in the above display substrate provided by embodiments of the present disclosure, as shown in FIG. 2A and FIG. 3A, an orthographic projection of each second signal line 51 on the base substrate 1 falls within an orthographic projection of the first organic layer 4 on the base substrate 1, the second organic layer 6 covers a top surface and side surfaces of the second signal line 51, and the second organic layer 6 is arranged in contact with the first organic layer 4. In this way, the second organic layer 6 completely wraps the second signal line 51, which may protect the second signal line 51 from erosion.

In some embodiments, in the above display substrate provided by embodiments of the present disclosure, as shown in FIG. 4A and FIG. 5A, each second signal line 51 at least covers a top surface of the first organic layer 4. Thus, the strength of the second signal line 51 may be improved.

In some embodiments, in the above display substrate provided by embodiments of the present disclosure, as shown in FIG. 4A and FIG. 5A, each second signal line 51 also covers side surfaces of the first organic layer 4, and the second signal line 51 is arranged in contact with the base substrate 1. In this way, the second signal line 51 completely wraps the first organic layer 4, which may increase the modulus of each bridge region Q2 and further improve the strength of each bridge region Q2.

In some embodiments, in the above display substrate provided by embodiments of the present disclosure, as shown in FIG. 4A and FIG. 5A, each second organic layer 6 covers the top surface and the side surfaces of the second signal line 51, and the second organic layer 6 is arranged in contact with the base substrate 1. In this way, the second organic layer 6 completely wraps the second signal line 51, on one hand, the second signal line 51 may be protected from erosion, and on the other hand, the strength of each bridge region Q2 is further improved.

In some embodiments, as shown in FIG. 4A and FIG. 5A, the second organic layers 6 in the bridge regions Q2 are arranged at intervals, the first organic layers 4 in the bridge regions Q2 are arranged at intervals, and a distance between two adjacent spaced second organic layers 6 is less than or equal to a distance between two adjacent spaced first organic layers 4. Therefore, the second organic layers 6 may completely wrap the first organic layers 4, and strength of the bridge regions Q2 may be improved.

In some embodiments, in order to further improve the strength of the bridge regions, in the above display substrate provided by embodiments of the present disclosure, as shown in FIG. 3A, FIG. 3B, FIG. 3C, FIG. 5A, FIG. 5B and FIG. 5C, FIG. 3B is a schematic diagram of a plane structure of an inorganic layer 7 in a bridge region Q2 in FIG. 3A, FIG. 3C is a schematic diagram of yet another plane structure of an inorganic layer 7 in a bridge region Q2 in FIG. 3A, FIG. 5B is a schematic diagram of a plane structure of an inorganic layer 7 in a bridge region Q2 in FIG. 5A, FIG. 5C is a schematic diagram of yet another plane structure of an inorganic layer 7 in a bridge region Q2 in FIG. 5A, each bridge region Q2 also includes the inorganic layer 7 arranged on the side of the second organic layer 6 facing away from the base substrate 1, the inorganic layer 7 covers the second organic layer 6 and is arranged in contact with the base substrate 1, and the inorganic layer 7 has a hollow-out structure. In this way, the inorganic layer 7 on an outside of the second organic layer 6 may increase the modulus and improve the strength of the bridge region Q2. Moreover, the inorganic layer 7 has the hollow-out structure, which may improve the stretching property and prevent the cracking of the bridge region Q2.

In some embodiments, in the above display substrate provided by embodiments of the present disclosure, as shown in FIG. 3B and FIG. 5B, the inorganic layer 7 of each bridge region Q2 includes a top structure 71 arranged opposite to the base substrate 1 and two side structures 72 arranged in contact with the base substrate 1. The top structure 71 has first hollow-out structures 711 penetrating through the top structure 71 in a thickness direction of the top structure 71. In this way, an area of the inorganic layer 7 may be reduced by performing hollow-out design on the top structure 71 of the inorganic layer 7, and a breaking risk of the inorganic layer 7 may be reduced when the display substrate is stretched, so as to ensure that the signal lines of each bridge region Q2 will not break.

In some embodiments, in order to further reduce breaking of the signal lines of the bridge regions due to breaking of the inorganic layers, in the above display substrate provided by embodiments of the present disclosure, as shown in FIG. 3B and FIG. 5B, along the extension direction of the signal line (e.g. 51), each top structure 71 has a plurality of first hollow-out structures 711 evenly arranged at intervals in an extension direction of the signal line.

In some embodiments, a shape of each first hollow-out structure 711 may be round, square, etc., and the quantity and size of the first hollow structures 711 are designed according to the length of each bridge region Q2.

In some embodiments, as shown in FIG. 3B and FIG. 5B, a width of each first hollow-out structure 711 (e.g., perpendicular to a direction of the second signal line 51) may be smaller than a width of the second signal line 51 in the extension direction of the signal line (such as the second signal line 51). Thus, it may be avoided that each first hollow-out structure 711 is too large, resulting in short circuits of the second signal line 51 and the first signal line 31 during production. Preferably, an orthographic projection of each first hollow-out structure 711 on base substrate 1 is located within the orthographic projection of the second signal line 51 on base substrate 1.

In some embodiments, in order to further reduce breaking of the signal lines of the bridge regions due to breaking of the inorganic layers, in the above display substrate provided by embodiments of the present disclosure, as shown in FIG. 3A, FIG. 3C, FIG. 5A and FIG. 5C, the top structure 71 of each inorganic layer 7 has the first hollow-out structures 711 penetrating through the top structure 71 in the thickness direction of the top structure 71, and each side structure 72 of each inorganic layer 7 has second hollow-out structures 721 penetrating through the side structure 72 in a thickness direction of the side structure 72. In this way, the area of the inorganic layer 7 may be further reduced, and the breaking risk of the inorganic layer 7 is further avoided.

In some embodiments, in the above display substrate provided by embodiments of the present disclosure, as shown in FIG. 3C and FIG. 5C, the second hollow-out structures 721 are interconnected with the first hollow-out structures 711. Thus, the extension direction of each inorganic layer 7 along the signal lines is equivalent to including a plurality of independent structures, and certainly, the second hollow-out structures 721 and the first hollow-out structures 711 may also be arranged independently.

In some embodiments, in the above display substrate provided by embodiments of the present disclosure, as shown in FIG. 2A, FIG. 3A, FIG. 4A and FIG. 5A, each island region Q1 includes a first source-drain metal layer SD1, a first planarization layer PLN1, a second source-drain metal layer SD2 and a second planarization layer PLN2 stacked in sequence in the direction facing away from the base substrate 1, the first signal line 31 is arranged on the same layer as the first source-drain metal layer SD1, the first organic layer 4 is arranged on the same layer as the first planarization layer PLN1, the second signal line 51 is arranged on the same layer as the second source-drain metal layer SD2, and the second organic layer 6 is arranged on the same layer as the second planarization layer PLN2. In this way, graphs of the first signal line 31 and the first source-drain metal layer SD1 may be formed through a primary composition process, graphs of the first organic layer 4 and the first planarization layer PLN1 may be formed through the primary composition process, graphs of the second signal line 51 and the second source-drain metal layer SD2 may be formed through the primary composition process, graphs of the second organic layer 6 and the second planarization layer PLN2 are formed through the primary composition process, and a process of independently preparing the first signal line 31, the second signal line 51, the first organic layer 4 and the second organic layer 6 does not need to be added, which may simplify a preparation process, save production cost and improve production efficiency.

In some embodiments, in the above display substrate provided by embodiments of the present disclosure, as shown in FIG. 2A, FIG. 3A, FIG. 4A and FIG. 5A, each island region Q1 further includes a first inorganic encapsulation layer CVD1, an organic encapsulation layer OC and a second inorganic encapsulation layer CVD2 stacked in sequence on a side of the second planarization layer PLN2 facing away from the base substrate 1. The inorganic layer 7 of each bridge region Q2 in FIG. 3A and FIG. 5A includes a first sub-inorganic layer 73 and a second sub-inorganic layer 74 arranged in a stacked mode. The first sub-inorganic layer 73 is arranged on the same layer as the first inorganic encapsulation layer CVD1, and the second sub-inorganic layer 74 is arranged on the same layer as the second inorganic encapsulation layer CVD2. In some embodiments, since the first inorganic encapsulation layer CVD1 and the second inorganic encapsulation layer CVD2 generally use the same mask (mask plate) for composition, the first sub-inorganic layer 73, the second sub-inorganic layer 74, the first inorganic encapsulation layer CVD1 and the second inorganic encapsulation layer CVD2 may be formed through the primary composition process, and a process of independently preparing the first sub-inorganic layer 73 and the second sub-inorganic layer 74 does not need to be added, which may simplify a preparation process, save production cost and improve production efficiency.

In some embodiments, as shown in FIG. 4A, a height of each bridge region Q2 (a distance from an upper surface of an outermost layer of the bridge region facing away from the base substrate to an upper surface of the base substrate 1) is smaller than a distance from an upper surface of the second source-drain metal layer SD2 of each island region Q1 to the upper surface of the base substrate 1. This design avoids too much thickness of the bridge region Q2, thus ensuring an overall height and elasticity of the bridge region Q2. For example, a distance from an upper surface of the second signal line 51 of the bridge region Q2 to the upper surface of the base substrate 1 is less than a distance from an upper surface of the second source-drain metal layer SD2 of the island region Q1 to the upper surface of base substrate 1.

In some embodiments, since the present disclosure is provided with an independent bridge region, and each bridge region is provided with only one signal line on the same layer, so that there is more space to design the bending structure of the bridge region and further improve the stretching property, so that in the display substrate provided by embodiments of the present disclosure, as shown in FIG. 1, the shape of the bridge region Q2 may be a curve, and the shape of the signal lines (31 and 51) is the same as that of the bridge region Q2.

In some embodiments, in the above display substrate provided by embodiments of the present disclosure, as shown in FIG. 2B, FIG. 3D, FIG. 4B and FIG. 5D, FIG. 2B is a schematic diagram of an amplified structure of three bridge regions Q2 in FIG. 2A, FIG. 3D is a schematic diagram of an amplified structure of three bridge regions Q2 in FIG. 3A, FIG. 4B is a schematic diagram of an amplified structure of three bridge regions Q2 in FIG. 4A, FIG. 5D is a schematic diagram of an amplified structure of three bridge regions Q2 in FIG. 5A, and line widths of the signal lines (31 and 51) range from 2.5 μm to 6 μm. For example, a line width W1 of the first signal line 31 ranges from 2.5 μm to 6 μm, and a line width W2 of the second signal line 51 ranges from 2.5 μm to 6 μm.

In some embodiments, in the above display substrate provided by embodiments of the present disclosure, as shown in FIG. 2B, FIG. 3D, FIG. 4B and FIG. 5D, a distance D1 between an edge of the orthographic projection of each first organic layer 4 on the base substrate 1 and an edge of an orthographic projection of each first signal line 31 on the base substrate 1 is greater than or equal to 1 μm. A distance D2 between an edge of the orthographic projection of each second organic layer 6 on the base substrate 1 and an edge of the orthographic projection of each second signal line 51 on the base substrate 1 is greater than or equal to 1 μm.

In some embodiments, in the above display substrate provided by embodiments of the present disclosure, as shown in FIG. 1, FIG. 2B, FIG. 3D, FIG. 4B and FIG. 5D, for each bridge region Q2 connecting two adjacent island regions Q1, a distance D3 between the adjacent bridge regions Q2 is greater than 3 μm, so that a distance between the second signal lines 51 of the two adjacent bridge regions Q2 is greater than or equal to 5 μm.

In some embodiments, as shown in FIG. 1, FIG. 2B and FIG. 3D, the width of each first signal line 31 and the width of each second signal line 51 may be the same, or the width of each first signal line 31 may be larger than the width of each second signal line 51, or the width of each second signal line 51 may be larger than the width of each first signal line 31.

In some embodiments, as shown in FIG. 1, the first signal lines 31 and the second signal lines 51 may be gate lines, data lines, power lines, sensing signal lines, etc., and the widths of the bridge regions Q2 may also be unequal, for example, the width of the bridge region Q2 provided with the power line will be larger.

In some embodiments, as shown in FIG. 1, FIG. 2A, FIG. 3A, FIG. 4A and FIG. 5A, the line width W1 of the first signal lines 31 is smaller than the line width W2 of the second signal lines 51. The first signal lines 31 may be the data lines (for example, data), and the second signal lines 51 may be the power lines (for example, VDD). The first signal lines 31 may be the data lines, and the second signal lines 51 may be the sensing signal lines SL (for example, applied to a 3T1C pixel circuit).

In some embodiments, as shown in FIG. 1, FIG. 2A, FIG. 3A, FIG. 4A and FIG. 5A, in a first direction (for example, a horizontal direction in FIG. 1), the line width W1 of the first signal lines 31 is smaller than the line width W2 of the second signal lines 51, the first signal lines 31 may be scan lines (for example, scan), and the second signal lines 51 may be initial signal lines (for example, vinit); and in a second direction (such as a vertical direction in FIG. 1), the first signal lines 31 may be the data lines (such as data), and the second signal lines 51 may be the power lines (such as VDD).

In some embodiments, as shown in FIG. 1, FIG. 2A, FIG. 3A, FIG. 4A and FIG. 5A, in the first direction (for example, the horizontal direction in FIG. 1), the line width W1 of the first signal lines 31 is smaller than the line width W2 of the second signal lines 51, and signals transmitted on the second signal lines 51 and the first signal lines 31 may be the same, for example, as the scan lines (for example, scan) or the initial signal lines (for example, vinit); and in the second direction (for example, the vertical direction in FIG. 1), the signals transmitted on the second signal lines 51 and the first signal lines 31 may be the same, for example, both the data lines (for example, data) or the power lines (for example, VDD).

In some embodiments, in the above display substrate provided by embodiments of the present disclosure, as shown in FIG. 1, FIG. 2A, FIG. 3A, FIG. 4A and FIG. 5A, each island Q1 region also includes a first passivation layer PVX1, a second passivation layer PVX2, an anode 8, a pixel definition layer PDL, a light-emitting layer 9 and a cathode 10 stacked between the second planarization layer PLN2 and the first inorganic encapsulation layer CVD1 in sequence in the direction facing away from the base substrate 1, and a barrier layer BR, a buffer layer BF, an active layer ACT, a first gate insulation layer GI1, a first gate electrode layer G1, a second gate insulation layer GI2, a second gate electrode layer G2 and an interlayer insulation layer ILD stacked between the base substrate 1 and the first source-drain metal layer SD1 in sequence in the direction facing away from the base substrate 1. Each sub-pixel 2 of the island region Q1 includes a pixel circuit and a light-emitting apparatus, the pixel circuit includes a thin-film transistor and a storage capacitor, the first source-drain metal layer SD1 includes a source S and a drain D, the second source-drain metal layer SD2 includes a lap-joint part 12, a data line, etc., the first gate electrode layer G1 includes a gate electrode G1 and a first electrode plate cst1 of the storage capacitor, the second gate electrode layer G2 includes a second electrode plate cst2 of the storage capacitor, the anode 8 is electrically connected with the lap-joint part 12 located in the second source-drain metal layer SD2 through a via hole penetrating through the second planarization layer PLN2, the first passivation layer PVX1 and the second passivation layer PVX2 in sequence, and the lap-joint part 12 is electrically connected with the drain D through a via hole penetrating through the first planarization layer PLN1. The thin-film transistor is composed of the active layer ACT, the gate electrode of the first gate electrode layer G1, and the source and the drain of the first source-drain metal layer SD1, and the anode 8, the light-emitting layer 9 and the cathode 10 constitute the light-emitting apparatus.

In some embodiments, as shown in FIG. 2A, FIG. 3A, FIG. 4A and FIG. 5A, the barrier layer BR, the buffer layer BF, the first gate insulation layer GI1, the second gate insulation layer GI2, the interlayer insulation layer ILD, the first passivation layer PVX1 and the second passivation layer PVX2 are all inorganic film layers, and the inorganic layer is prone to breaking. The present disclosure etches all the above inorganic film layers located in each bridge region Q2 to prevent the bridge region Q2 from breaking during stretching.

In some embodiments, as shown in FIG. 2A, FIG. 3A, FIG. 4A and FIG. 5A, a distance between each bridge region Q2 (such as the second organic layer 6) and the encapsulation layer (such as the first inorganic encapsulation layer CVD1) of each island region Q1 is larger than a distance between each bridge region Q2 (such as the second organic layer 6) and the buffer layer BF of each island region Q1, and is smaller than a distance between each bridge region Q2 (such as the second organic layer 6) and the first gate insulation layer GI1 of each island region Q1, and in this design, the encapsulation layers of each island region Q1 form an internal shrinkage structure to avoid extrusion damage to the encapsulation layers of each island region Q1 when stretching of each bridge region changes.

In some embodiments, each anode may include a transparent conductive film/metal film/transparent conductive film three-layer stacked structure, in which a transparent conductive film material may be made of indium tin oxide ITO or indium zinc oxide IZO, and the metal film may be Al, Ag, Cu and other metal films.

In some embodiments, each cathode may be made of any one or more of magnesium (Mg), silver (Ag), aluminum (Al), copper (Cu), and lithium (Li), or an alloy made of any one or more of these metals.

In some embodiments, each light-emitting apparatus may be an inorganic light emitting diode, may also be an organic light-emitting diode (OLED) made of an organic material, may further be a micro light-emitting diode (LED) or mini light emitting diode (mini LED). The embodiment of the present disclosure takes the light-emitting apparatus as the organic light-emitting diode as an example.

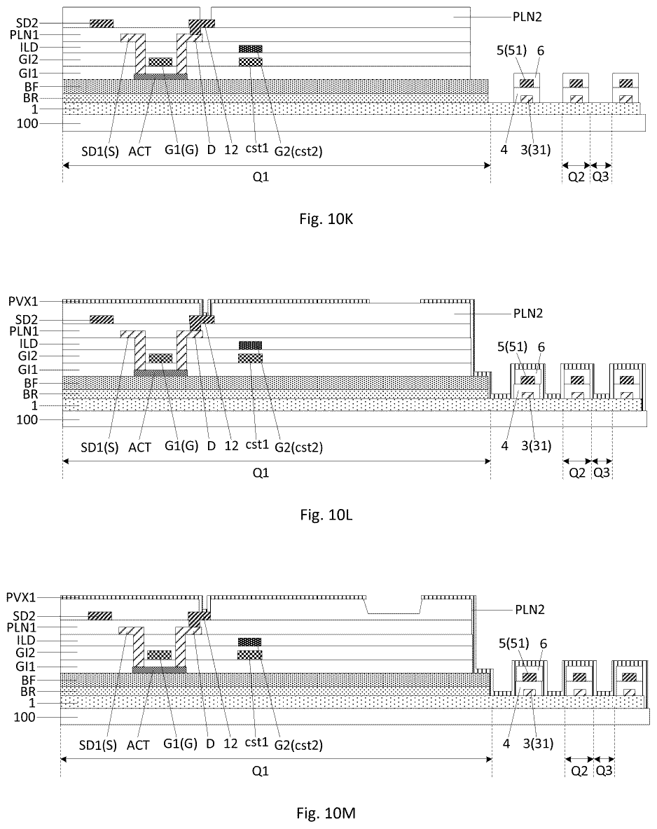

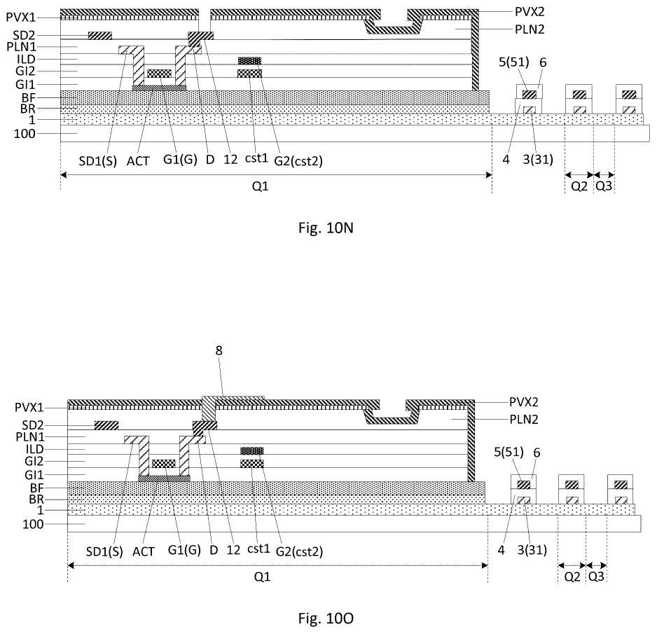

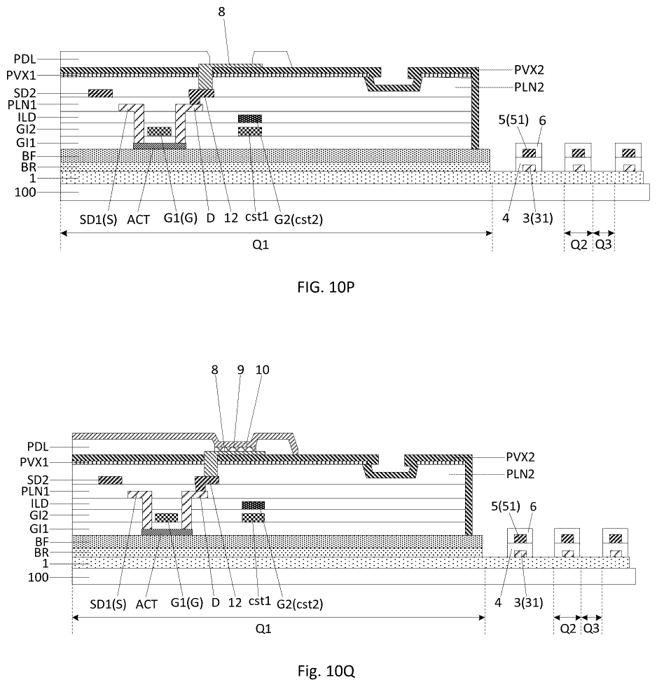

In some embodiments, each pixel circuit may adopt a variety of structures, for example, the pixel circuit may be of a structure including two transistors and one capacitor (2T1C), as shown in FIG. 6; or the pixel circuit may be of a structure including 3 transistors and 1 capacitor (3T1C), as shown in FIG. 7; or the pixel circuit may be of a structure including 7 transistors and 1 capacitor (7T1C), as shown in FIG. 8.

In some embodiments, in the above display substrate provided by embodiments of the present disclosure, as shown in FIG. 1, FIG. 2A, FIG. 3A, FIG. 4A and FIG. 5A, a groove 11 is formed in positions, close to the sub-pixels 2, of the second planarization layer PLN2 and the first passivation layer PVX1 of each island region Q1, each second inorganic layer PVX2 covers a bottom of the groove 11, the light-emitting layer 9 and the cathode 10 are both broken at the groove 11, and the organic encapsulation layer OC covers the second passivation layer PVX2 at the groove 11. Since the light-emitting layer 9 and the cathode 10 near each hole region Q3 are easily invaded by water and oxygen, the groove 11 may be arranged to surround all sub-pixels 2 in the island region Q1, or a groove 11 may be arranged around each sub-pixel 2. In this way, the groove 11 may combine the light-emitting layer 9 and the cathode 10 near each hole region Q3 with large hole resin of the light-emitting layer 9 and the cathode 10 located in the sub-pixels 2, so that the water and the oxygen may be prevented from invading into the light-emitting layer 9 and the cathode 10 in the sub-pixels 2 from each hole region Q3, thus ensuring normal display of a display product.

In some embodiments, the display substrate provided by the present disclosure may also include other functional film layers well known to those skilled in the art, which is not detailed herein.

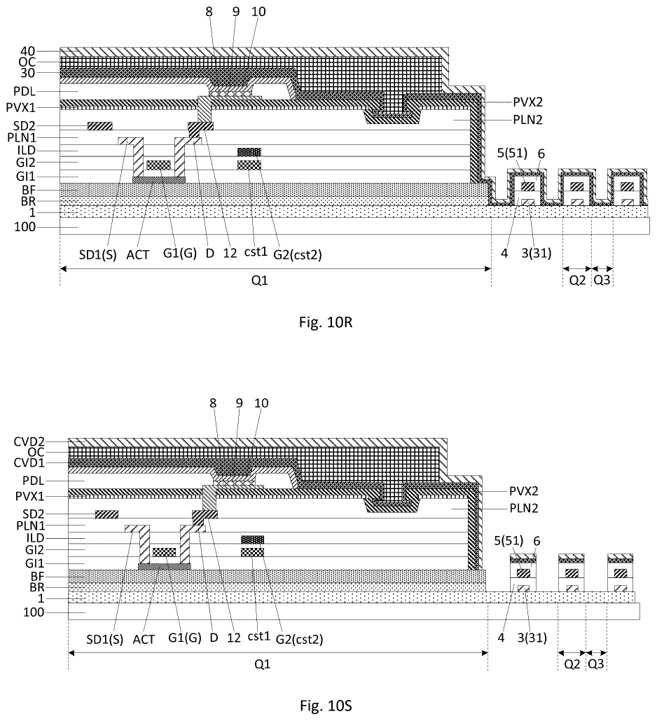

Based on the same inventive concept, the present disclosure further provides a method for manufacturing the above display substrate, as shown in FIG. 9, including:
S901, provide a base substrate, where the base substrate has a plurality of island regions, a plurality of bridge regions for connecting adjacent island regions and hole regions arranged between adjacent bridge regions, and the plurality of bridge regions arranged at intervals are connected between two adjacent island regions; and
S902, form at least one sub-pixel in each island region, and form a first metal layer, and a first organic layer and a second metal layer stacked in sequence in a direction facing away from the base substrate in at least one bridge region, where the first metal layer in each bridge region includes a first signal line for connecting with the sub-pixels in the adjacent island regions, and the second metal layer in each bridge region includes a second signal line for connecting with the sub-pixels in the adjacent island regions.

According to the method for manufacturing the display substrate provided by embodiments of the present disclosure, the plurality of independent bridge regions for connecting with two adjacent island regions are arranged between two adjacent island regions, and only one signal line is set in the same metal layer of each bridge region, so that the width of each bridge region may be reduced, the length of each bridge region is increased, and then the modulus of each bridge region is reduced by removing the corresponding inorganic layer of each bridge region, which can effectively improve the stretching capacity. In addition, the double-layer metal wiring design is adopted in each bridge region, on one hand, the strength of the signal lines of each bridge region may be increased, so that the signal lines of each bridge region are not prone to breaking when the display substrate is removed from the rigid base substrate in the preparation process; and on the other hand, the double-layer metal wiring design is adopted in each bridge region, and the signal lines of the upper and lower metal layers may be designed as the independent signal lines, which may reduce the quantity of the bridge regions, and there is more space to design the bending structure of each bridge region to further improve the stretching property. Therefore, the present disclosure may not only improve the stretching property of the display substrate, but also avoid breakage of the signal lines of each bridge region when the display substrate is removed from the rigid base substrate.

A process of forming each film layer in the present disclosure may include a composition process and a photolithography process, etc. The composition process may include film layer deposition, photoresist coating, mask exposure, development, etching, photoresist, stripping etc., while the photolithography process may include film layer coating, mask exposure, development, etc. Evaporation, deposition, coating, spreading, etc. are all mature preparation processes in related technologies.

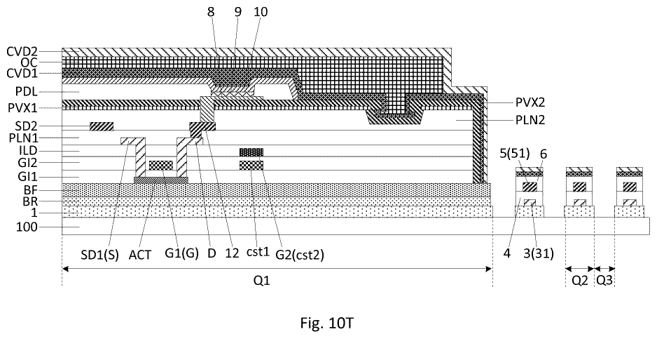

The display substrate shown in FIG. 2A is taken as an example below, and a manufacturing process of the display substrate shown in FIG. 2A is illustrated in detail, and may include the following steps.
(1) the base substrate 1 including a flexible layer structure is taken as an example, the base substrate 1 is divided into the island regions Q1, the bridge regions Q2 and the hole regions Q3, the base substrate 1 is formed on a glass substrate 100, a barrier layer BR is formed on the base substrate 1, a buffer layer BF is formed on the barrier layer BR, an active layer film (such as an amorphous silicon layer) is deposited on the buffer layer BF, after dehydrogenation of amorphous silicon layer at a high temperature, excimer laser annealing (ELA) is used to transform amorphous silicon into polysilicon, then a polysilicon layer is subject to composition by a composition process to form an active layer ACT, and the active layer ACT may include some ion doping, as shown in FIG. 10A.
(2) A first gate insulation layer GI1 is formed on the active layer ACT, as shown in FIG. 10B.
(3) A layer of metal film (a first gate electrode layer G1) is deposited on the first gate insulation layer GI1, composition of the metal film is performed through the composition process, and a gate electrode G, a gate line (not shown) and a first electrode plate cst1 are formed on the first insulation layer GI1, as shown in FIG. 10C.
(4) A second gate insulation layer GI2 is formed on the gate electrode G, as shown in FIG. 10D.
(5) A layer of metal film (a second gate electrode layer G2) is deposited on the second gate insulation layer GI2, composition of the metal film is performed through the composition process, a second electrode plate cst2 is formed on the second insulation layer GI2, and a position of the first electrode plate cst1 corresponds to a position of the second electrode plate cst2, as shown in FIG. 10E.
(6) An interlayer insulation layer ILD is formed on the second gate electrode layer G2, as shown in FIG. 10F; and at the same time, composition is performed on the barrier layer BR, the buffer layer BF, the first gate insulation layer GI1, the second gate insulation layer GI2 and the interlayer insulation layer ILD, all the film layers located in each bridge region Q2 and each hole region Q3 are removed, the base substrate 1 is exposed in each bridge region Q2 and each hole region Q3, and meanwhile, via holes penetrating through the first gate insulation layer GI1, the second gate insulation layer GI2 and the interlayer insulation layer ILD are etched above both ends of the active layer ACT of each island region Q1 for subsequent electrical connection with the source and the drain, as shown in FIG. 10G.
(7) A layer of metal film (SD1) is deposited on the interlayer insulation layer ILD, composition is performed on the metal film through the composition process, and a source S and a drain D located in each island region Q1 and a first signal line 31 located in each bridge region Q2 are formed on the interlayer insulation layer ILD, as shown in FIG. 10H.
(8) A flat film made of an organic material is coated on the SD1, a first planarization layer PLN1 is formed in each island region Q1 through mask, exposure and development processes, positions, corresponding to the drain D and each hole region Q3, of the first planarization layer PLN1 are developed out, and a first organic layer 4 covering the first signal line 31 is formed in each bridge region Q2, as shown in FIG. 101.
(9) A layer of metal film (SD2) is deposited on the first planarization layer PLN1, composition is performed on the metal film through the composition process, a lap-joint part 12 located on the first planarization layer PLN1 is formed in each island region Q1, and a second signal line 51 is formed in each bridge region Q2, as shown in FIG. 10J.
(10) A flat film made coated with an organic material is formed on a film layer where the lap-joint part 12 is located, a second planarization layer PLN2 is formed through mask, exposure and development processes, positions, corresponding to the lap-joint part 12 and each hole region Q3, of the second planarization layer PLN2 are developed out, and a second organic layer 6 covering the second signal line 51 is formed in each bridge region Q2, as shown in FIG. 10K.
(11) An inorganic insulation material film layer is deposited on the second planarization layer PLN2, composition is performed on the inorganic insulation material film layer, and a slot penetrating through the inorganic insulation material film layer is formed on the periphery of all sub-pixels in each island region Q1, as shown in FIG. 10L.
(12) A first passivation layer PVX1 is used as a mask plate to perform exposure and development on the second planarization layer PLN2, so as to form a groove 11 formed below the slot, as shown in FIG. 10M.
(13) An inorganic insulation material film layer is deposited on the first passivation layer PVX1, composition is performed on the inorganic insulation material film layer and the first passivation layer PVX1, positions, corresponding to the lap-joint part 12, of the inorganic insulation material film layer and the first passivation layer PVX1 are etched facing away, and all the inorganic insulation material film layers in each bridge region Q2 and each hole region Q3 are removed, so as to form a second passivation layer PVX2 in each island Q1, as shown in FIG. 10N.
(14) A conductive film is deposited on the second passivation layer PVX2, composition is performed on the conductive film through the composition process to form an anode 8, and the anode 8 is electrically connected with the lap-joint part 12 through a via hole penetrating through the second passivation layer PVX2, the first passivation layer PVX1 and the second planarization layer PLN2, as shown in FIG. 100.
(15) A pixel definition film is coated on the anode 8, a pixel definition layer PDL is formed in each island region Q1 through mask, exposure and development processes, a pixel opening is formed in the pixel definition layer PDL of each island region Q1, the pixel definition film in the pixel opening is developed facing away to expose a surface of the anode 8, and moreover, positions, corresponding to each hole region Q3 and each bridge region Q2, of the pixel definition film are developed facing away, as shown in FIG. 10P.
(16) A light-emitting layer 9 and a cathode 10 are formed in sequence on the pixel definition layer PDL, the light-emitting layer 9 is formed in the pixel opening of the pixel definition layer PDL and connected with the anode 8, and the light-emitting layer 9 and the cathode 10 are broken at the position of the groove 11 respectively, as shown in FIG. 10Q.
(17) A first inorganic encapsulation film 30 is formed on the cathode 10, an organic encapsulation film 30 is formed on the first inorganic encapsulation film 30, the organic encapsulation film is exposed and developed, an organic encapsulation layer OC is formed in each island region Q1, all organic encapsulation films in each bridge region Q2 and each hole region Q3 are removed, and then a second inorganic encapsulation film 40 is formed on the organic encapsulation layer OC, as shown in FIG. 10R.
(18) Composition is performed on the first inorganic encapsulation film 30 and the second inorganic encapsulation film 40, the first inorganic encapsulation film 30 and the second inorganic encapsulation film 40 corresponding to each hole region Q3 form a first inorganic encapsulation layer CVD1 and a second inorganic encapsulation layer CVD2 in each island region Q1, and the first inorganic encapsulation film 30 and the second inorganic encapsulation film 40 are retained in each bridge region Q2, as shown in FIG. 10S.
(19) The first inorganic encapsulation film 30 and the second inorganic encapsulation film 40 are used as mask plates to perform composition on the base substrate 1, and the base substrate 1 of each hole region Q3 is removed, as shown in FIG. 10T.
(20) The first inorganic encapsulation film 30 and the second inorganic encapsulation film 40 of each bridge region Q2 are removed, to form the display substrate as shown in FIG. 2A.

Finally, a protection film is pasted on the second inorganic encapsulation layer CVD2, then, the glass substrate 100 is stripped through a laser stripping process, the protection film is removed, and the stretchable display substrate is formed.

It should be noted that embodiments of the present disclosure are illustrated by using the method for manufacturing the display substrate shown in FIG. 2A as an example. The method for manufacturing the display substrate shown in FIG. 3A is similar to that shown in FIG. 2A, except that the first inorganic encapsulation film 30 and the second inorganic encapsulation film 40 of each bridge region Q2 are retained in the above step (19). A hollow-out structure shown in FIG. 3B or 3C is formed on the first inorganic encapsulation film 30 and the second inorganic encapsulation film 40. The method for manufacturing the display substrate shown in FIG. 4A is similar to that shown in FIG. 2A, except that when the second signal line 51 is formed in the above step (9), the second signal line 51 covers the first organic layer 4, and when the second organic layer 6 is formed in the above step (10), the second organic layer 6 covers the second signal line 51 and is arranged in contact with the base substrate 1. The method for manufacturing the display substrate shown in FIG. 5A is similar to that shown in FIG. 2A, except that when the second signal line 51 is formed in the above step (9), the second signal line 51 covers the first organic layer 4, when the second organic layer 6 is formed in step (10), the second organic layer 6 covers the second signal line 51 and is arranged in contact with the base substrate 1, the first inorganic encapsulation film 30 and the second inorganic encapsulation film 40 of each bridge region Q2 are retained in step (19), and a hollow-out structure shown in FIG. 5B or FIG. 5C is formed on the first inorganic encapsulation film 30 and the second inorganic encapsulation film 40.

Based on the same inventive idea, the present disclosure also provides a display apparatus, including any of the above display substrates provided by embodiments of the present disclosure. The display apparatus may be a mobile phone, a tablet computer, a television, a display, a laptop computer, a digital photo frame, a navigator and any other products or components with display functions. The implementation of the display apparatus be referred to the above embodiments of the display substrate, and the repetition will not be repeated.

The display apparatus may be an organic light-emitting diode display panel, a quantum dot light-emitting diode display panel, a display module, a curved screen mobile phone, a smart watch, and any other products or components with display functions.

Embodiments of the present disclosure provide the display substrate, the manufacturing method thereof and the display apparatus. The plurality of independent bridge regions for connecting with two adjacent island regions are arranged between two adjacent island regions, and only one signal line is set in the same metal layer of each bridge region, so that the width of each bridge region may be reduced, the length of each bridge region is increased, and then the modulus of each bridge region is reduced by removing the corresponding inorganic layer of each bridge region, which may effectively improve the stretching capacity. In addition, the double-layer metal wiring design is adopted in each bridge region, on one hand, the strength of the signal lines of each bridge region may be increased, so that the signal lines of each bridge region are not prone to breaking when the display substrate is removed from the rigid base substrate in the preparation process; and on the other hand, the double-layer metal wiring design is adopted in each bridge region, and the signal lines of the upper and lower metal layers may be designed as the independent signal lines, which may reduce the quantity of the bridge regions, and there is more space to design the bending structure of each bridge region to further improve the stretching property. Therefore, the present disclosure may not only improve the stretching property of the display substrate, but also avoid breakage of the signal lines of each bridge region when the display substrate is removed from the rigid base substrate.

Although preferred embodiments of the present disclosure are already described, once those skilled in the art know a basic creative concept, addition change and modifications may be made on the embodiments. Therefore, appended claims are intended to be illustrated to include the preferred embodiments and all changes and modifications falling within the scope of the present disclosure.

Obviously, those skilled in the art may perform various alterations and variations on the present disclosure without departing from the spirit and range of the present disclosure. Therefore, if these modifications and variations of the present disclosure fall within the claims of the present disclosure and the range of the equivalent technology thereof, the present disclosure is also intended to include these modifications and variations.

1. A display substrate, comprising: a base substrate, a plurality of island regions on a side of the base substrate, a plurality of bridge regions for connecting adjacent island regions, and hole regions arranged between adjacent bridge regions; wherein,
each island region comprises at least one sub-pixel, wherein the plurality of bridge regions arranged at intervals are connected between two adjacent island regions; and
at least one bridge region comprises: a first metal layer, a first organic layer and a second metal layer arranged in a direction facing away from the base substrate, wherein the first metal layer in each bridge region comprises a first signal line for connecting the sub-pixels in the adjacent island regions, and the second metal layer in each bridge region comprises a second signal line for connecting the sub-pixels in the adjacent island regions.

2. The display substrate according to claim 1, wherein each bridge region further comprises a second organic layer arranged on a side of the second metal layer facing away from the base substrate, and an orthographic projection of the second organic layer on the base substrate and an orthographic projection of the first organic layer on the base substrate are both within a range of the base substrate.

3. The display substrate according to claim 2, wherein the first organic layer at least covers a top surface of the first signal line.

4. The display substrate according to claim 3, wherein the first organic layer further covers a side surface of the first signal line, and the first organic layer is arranged in contact with the base substrate.

5. The display substrate according to claim 4, wherein an orthographic projection of the second signal line on the base substrate fall within the orthographic projection the first organic layer on the base substrate.

6. The display substrate according to claim 5, wherein the second organic layer covers a top surface of the second signal line and a side surface of the second signal line, and the second organic layer is arranged in contact with the first organic layer.

7. The display substrate according to claim 4, wherein the second signal line at least covers the top surface of the first organic layer.

8. The display substrate according to claim 7, wherein the second signal line further covers a side surface of the first organic layer, and the second signal line is arranged in contact with the base substrate.

9. The display substrate according to claim 8, wherein the second organic layer covers a top surface of the second signal line and a side surface of the second signal line, and the second organic layer is arranged in contact with the base substrate.

10. The display substrate according to claim 2, wherein each bridge region further comprises an inorganic layer arranged on a side of the second organic layer facing away from the base substrate, the inorganic layer covers the second organic layer and is arranged in contact with the base substrate, and the inorganic layer has a hollow-out structure.

11. The display substrate according to claim 10, wherein the inorganic layer comprises a top structure arranged opposite to the base substrate and two side structures arranged in contact with the base substrate, and the top structure has a first hollow-out structures penetrating through the top structure in a thickness direction of the top structure.

12. The display substrate according to claim 11, wherein the top structure has a plurality of the first hollow-out structures evenly arranged at intervals in an extension direction of the second signal line.

13. The display substrate according to claim 11 wherein the side structure has a second hollow-out structure penetrating through the side structure in a thickness direction of the side structure.

14. The display substrate according to claim 13, wherein the second hollow-out structure is interconnected with the first hollow-out structure.

15. The display substrate according to claim 10, wherein the island region comprises a first source-drain metal layer, a first planarization layer, a second source-drain metal layer and a second planarization layer stacked in sequence in a direction facing away from the base substrate;
the first signal line is arranged on the same layer as the first source-drain metal layer, the first organic layer is arranged on the same layer as the first planarization layer, the second signal line is arranged on the same layer as the second source-drain metal layer, and the second organic layer is arranged on the same layer as the second planarization layer.

16. The display substrate according to claim 15, wherein the island region further comprises a first inorganic encapsulation layer, an organic encapsulation layer and a second inorganic encapsulation layer stacked in sequence on a side of the second planarization layer facing away from the base substrate;
the inorganic layer comprises a first sub-inorganic layer and a second sub-inorganic layer arranged in a stacked mode, the first sub-inorganic layer is arranged on the same layer as the first inorganic encapsulation layer, and the second sub-inorganic layer is arranged on the same layer as the second inorganic encapsulation layer.

17. The display substrate according to claim 1, wherein a shape of the bridge region is a curve line, and a shape of the first signal line and a shape of the second signal line are is the same as the shape of the bridge region.

18. The display substrate according to claim 2, wherein a distance between an edge of the orthographic projection of the first organic layer on the base substrate and an edge of an orthographic projection of the first signal line on the base substrate is greater than or equal to 1 μm; and
a distance between an edge of the orthographic projection of the second organic layer on the base substrate and an edge of an orthographic projection of the second signal line on the base substrate is greater than or equal to 1 μm.

19. A display apparatus, comprising the display substrate according to claim 1.

20. A method for manufacturing a display substrate, comprising:
providing a base substrate, wherein the base substrate has a plurality of island regions, a plurality of bridge regions for connecting adjacent island regions and hole regions arranged between adjacent bridge regions, wherein the plurality of bridge regions arranged at intervals are connected between two adjacent island regions; and
forming at least one sub-pixel in each island region, and forming a first metal layer, a first organic layer and a second metal layer stacked in sequence in a direction facing away from the base substrate in at least one bridge region, wherein the first metal layer in each bridge region comprises a first signal line for connecting the sub-pixels in the adjacent island regions, and the second metal layer in each bridge region comprises a second signal line for connecting the sub-pixels in the adjacent island regions.
